(19) United States
(12) Patent Application Publication
(10) Pub. No.: US 2021/0240233 A1
(43) Pub. Date: Aug. 5, 2021

(54) HOUSING FOR A MEDICAL DEVICE

(71) Applicant: ADLINK Technology GmbH, Deggendorf (DE)

(72) Inventor: Walter Steinbeisser, Pilsting (DE)

(73) Assignee: ADLINK Technology GmbH, Deggendorf (DE)

(21) Appl. No.: 16/975,100

(22) PCT Filed: Mar. 16, 2020
(86) PCT No.: PCT/EP2020/057082

§ 371 Date: Aug. 21, 2020

(30) Foreign Application Priority Data
Apr. 8, 2019 (EP) 19167733.5

(51) Int. Cl. G06F 1/18; H05K 5/02

(52) U.S. Cl. CPC G06F 1/182; H05K 5/0217

(57) ABSTRACT

A housing for a medical device, comprising at least one touch-sensitive display unit or a support for a touch-sensitive display unit, wherein the housing comprises at least a first housing part and a second housing part, which can be detachably connected to the first housing part, the first housing part having first connecting members and the second housing part having second connecting members which cooperate with these first connecting members, the first and second connecting members configured to fasten the second housing part to the first housing part by an interlocking connection, wherein securing members are configured to secure the fastening of the second housing part to the first housing part and include a magnetic or magnetizable element configured to cooperate with a magnetic detaching device such that the securing members can be moved from a securing position to a detaching position by the magnetic field.

The present disclosure relates to a housing for a medical device, a detaching device for a housing and a method for opening such a housing.

Medical devices, for example monitors or computers, in which computer hardware, such as processor, memory etc., as well as a touch-sensitive display unit are integrated into a common housing, are generally known. Medical devices of this type are used in particular in operating rooms, medical airlock areas and intensive care units. These devices must therefore meet the high demands made on cleanability and sterilizability. In addition, it must also be possible to sterilize the housings of the devices with liquids, as a result of which the housings have to be protected against the penetration of moisture.

Housings of medical devices are usually made of several parts, wherein the housing parts should be detachably connected to one another to allow the device to be repaired.

A disadvantage of the known housings is that they have screw connections for mechanically securing the detachably connected housing parts. The screw heads of the screw connections and the contours around these screw heads are difficult to clean or disinfect, so that housings having screw connections of this type are unwanted for hygienic reasons.

Using this as a basis, an object of the present disclosure is to provide a housing for a medical device which, despite detachably connected housing parts, allows improved cleaning and disinfection of the housing.

This object is achieved by a housing comprising the features of independent claim 1. A detaching device for such a housing is the subject matter of the alternative independent claim 14 and a method for opening a housing is the subject matter of the alternative independent claim 15.

According to a first aspect, the present disclosure relates to a housing for a medical device. The device is in particular a monitor or a so-called medical PC, i.e. a computer for use in medical treatment rooms, in which the computer hardware, such as a processor, a memory etc., as well as a touch-sensitive display unit are integrated into a common housing. The housing comprises at least one touch-sensitive display unit or a mechanical support for such a touch-sensitive display unit. In an embodiment, the housing is configured in such a way that the display unit extends over the complete or substantially complete front side of the housing. The housing comprises at least a first housing part and a second housing part which can be detachably connected to the first housing part. The first housing part has first connecting members and the second housing part has second connecting members cooperating with these first connecting members when these housing parts are coupled. The first and second connecting members are configured to effect a fastening of the second housing part to the first housing part by means of an interlocking connection. An interlocking connection of this type is, for example, a hooking or otherwise meshing connection of the housing parts. Securing members are provided which are configured to secure the fastening of the second housing part to the first housing part. The securing members have a magnetic or magnetizable element which is configured for the purpose of cooperation with a magnetic detaching device in such a way that the securing members can be moved from a securing position to a detaching position by the magnetic field of the magnetic detaching device. The magnetic element can in particular be a permanent magnet. The magnetizable element can be an element which has ferromagnetic properties, for example an element made of iron. In an embodiment, the fastening of the second housing part to the first housing part is secured without screws and e.g. exclusively by these securing members. In an embodiment, the securing members are integrated into the housing and concealed.

The technical advantage of the housing according to the an embodiment of the present disclosure is that, due to the securing members which can be magnetically operated, screws for securing the fastening of the second housing part to the first housing part can be dispensed with, which considerably facilitates the cleanability and disinfectability of the housing.

According to an embodiment, the securing members have a latch which is spring-loaded and positioned in a securing position without the influence of external forces. The latch can, for example, be formed by a pin-like bolt that is provided in a shiftable or otherwise movable way in part of the housing, e.g. the first housing part, which is configured to receive the touch-sensitive display unit. This latch and its spring-loaded pretension into the securing position ensure that the first and second housing parts are secured against unwanted detachment of the interlocking connection and that the securing members have to be actively deactivated in order to be able to detach the interlocking connection.

According to an embodiment, the latch can be shifted, in particular by a translational movement in the direction of the longitudinal axis thereof, pivoted or moved in a combined shifting and pivoting movement. This movement can be used to move the latch from the securing position to the detaching position and vice versa.

According to an embodiment, the latch is mechanically coupled to the magnetic or magnetizable element, the magnetic or magnetizable element being configured to cooperate with the magnetic detaching device in such a way that due to the forces exerted by the magnetic detaching device on the magnetic or magnetizable element the latch can be moved from the securing position to the detaching position. Triggered by the magnetic detaching device, the securing of the connection which is caused by the latch can be deactivated so that the interlocking connection of the housing parts can be released.

According to an embodiment, the latch in the securing position is provided for engaging in a recess formed on the second housing part or the latch in the securing position engages behind a projection or an undercut provided on the second housing part. Due to this engaging or engaging behind it, mechanical securing is achieved between the first housing part in which the latch is mounted and the second housing part.

According to an embodiment, the first housing part has openings as first connecting members, in which projections provided at the second housing part as second connecting members engage interlockingly. Alternatively, an inverse design is conceivable, namely that the second housing part has openings as second connecting members, in which projections provided at the first housing part as first connecting members engage interlockingly. In this way, it is possible to achieve a secure fastening of the housing parts relative to one another. In an embodiment, the housing parts are pressed against each other by the interlocking connection, so that the interface between the housing parts can be made liquid-tight.

According to an embodiment, the interlocking connection between the second housing part and the first housing part is made by a projection that engages behind an undercut in sections. The projection can here be formed about the longitudinal axis thereof in a rotationally symmetric manner and can form a pin, for example. In this way it is possible to achieve a secure fastening of the housing parts relative to each other.

According to an embodiment, the interlocking connection between the second housing part and the first housing part is achieved by a plurality of projections which are shaped like a mushroom head or a dovetail and which engage in recesses or openings that cooperate with these projections. In this way it is possible to achieve the fastening of the housing parts relative to one another, in particular the fastening of the housing parts in such a way that they are pressed against one another.

According to an embodiment, the second housing part can be fastened to the first housing part by putting it on a first spatial direction and by shifting it in a second spatial direction that is transverse to the first spatial direction. In an embodiment, the second spatial direction runs parallel or substantially parallel to the plane which is spanned by the long and wide sides of the first housing part, i.e. the plane in which the display unit is arranged. For example, when the placement of the second housing part is carried out, projections can be inserted into openings that correspond therewith. By subsequently moving it along the second spatial direction, the projection can be shifted into a tapered area of the opening, thus achieving the interlocking connection.

According to an embodiment, the first and second spatial directions are perpendicular to each other. This ensures that the second housing part can be secured in a technically easy way by the securing members since the securing members only have to prevent the housing part from shifting in the second spatial direction.

According to an embodiment, a seal is provided at the interface between the first and second housing parts and seals the interface in a liquid-tight manner when the second housing part is fastened to the first housing part. In an embodiment, as a result of the interlocking connection of the housing parts relative to each other, a contact pressure of the housing parts with respect to this seal is achieved, so that the interface between the housing parts is made fluid-tight, in particular fluid-tight according to the IP65 standard.

The seal can be arranged in a circumferential recess of one of the housing parts. The seal can here be held in this recess by clamping and/or integral bonding, e.g. by gluing them together.

The seal can project into the recess of the housing part with a major part of the height thereof (greater than 50% of the seal height) and project beyond this recess with the minor part thereof (less than 50% of the seal height).

The seal can have a shape semicircular in cross-section. In an embodiment, the flattening which exists due to the semicircular shape abuts against the bottom of the recess into which the seal is inserted. The round section protrudes beyond the top of the recess and thus forms a sealing surface against which the rest of the housing part abuts.

According to an embodiment, when the second housing part is fastened to the first housing part, the transition between the first and second housing parts is flush with the surface. As a result, the cleanability and sterilizability of the housing can be further improved.

According to an embodiment, the second housing part is provided with at least one connection area having at least one plug connection interface. In order to close the connection area, a housing cover is provided, which can be magnetically fastened to the second housing part. This allows easy access to the plug connection interface and at the same time makes the housing easy to clean.

According to a further aspect, the present disclosure relates to a detaching device for a housing configured according to one of the above described embodiments. The detaching device comprises at least one contact section, which is configured for the interlocking contact with respect to at least one corner area or one edge of the first housing part, and a magnetic element, for example a permanent magnet or an electromagnet, which at least temporarily produces a magnetic field. The magnetic element is configured to cooperate with the magnetic or magnetizable element of the securing member in order to move the securing member from a securing position to a detaching position by means of the magnetic field of the magnetic element.

According to yet another aspect, the present disclosure relates to a method for opening a housing, the housing comprising at least a first housing part and a second housing part which can be detachably connected to the first housing part. Securing members are provided on the housing and are configured to secure the fastening of the second housing part to the first housing part. The method comprises the following steps:
arranging the housing, in which an opening of the first housing part is closed by the second housing part, on a magnetic detaching device;
moving the securing members from a securing position to a detaching position by applying a magnetic field of the magnetic detaching device to the securing members;
opening the housing by removing the second housing part from the first housing part.

The expressions “approximately”, “substantially” or “about” in the sense of the present disclosure refer to deviations from the exact value in each case by +/−10%, in some embodiments by +/−5% and/or deviations in the form of changes which are insignificant for the function.

Further developments, advantages and possible uses of embodiments of the present disclosure also result from the following description of embodiments and from the drawings. All the described and/or illustrated features, either individually or in any combination, are in principle the subject matter of the invention, irrespective of their combination in the claims or their back-reference. The content of the claims is also made an integral part of the description.

The present disclosure is explained in more detail below by means of embodiments on the basis of the drawings, wherein:

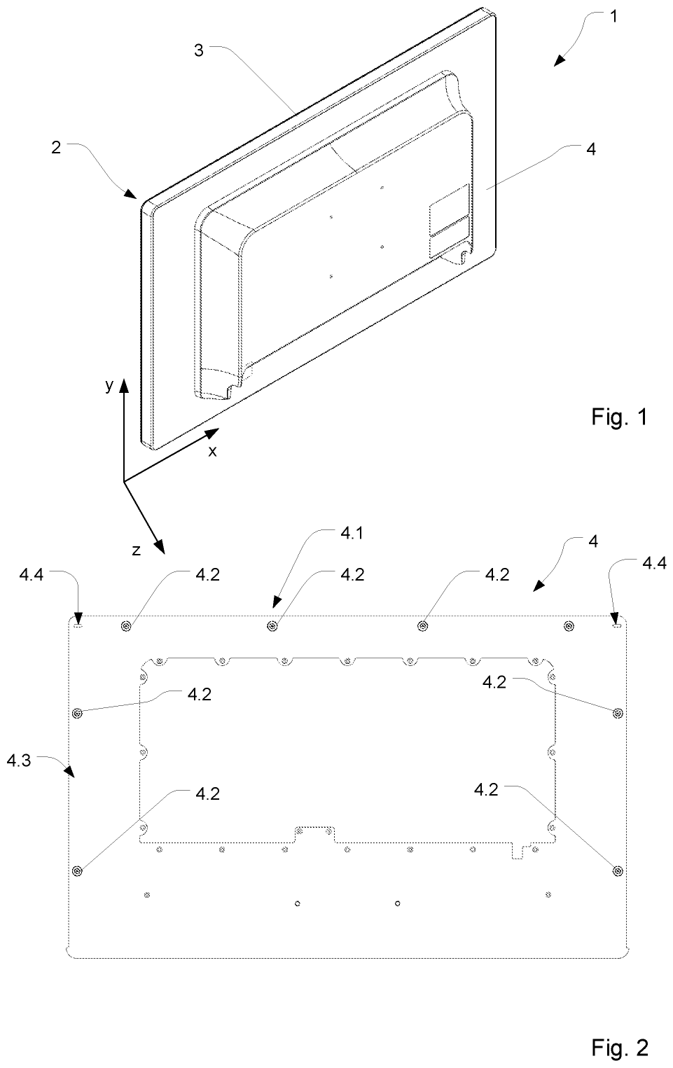

FIG. 1 shows by way of example an embodiment of a housing in a rear perspective view;

FIG. 2 shows by way of example a top view of the front side of the second housing part, to which the first housing part can be fastened;

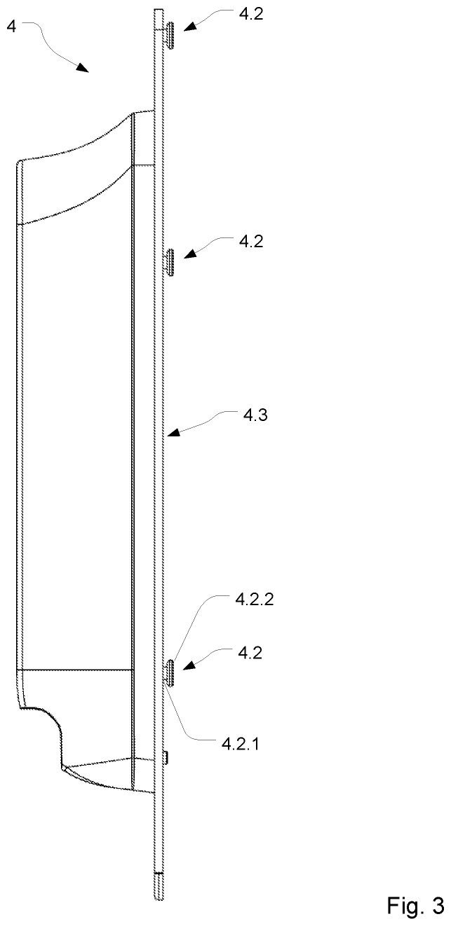

FIG. 3 shows by way of example a side view of a second housing part;

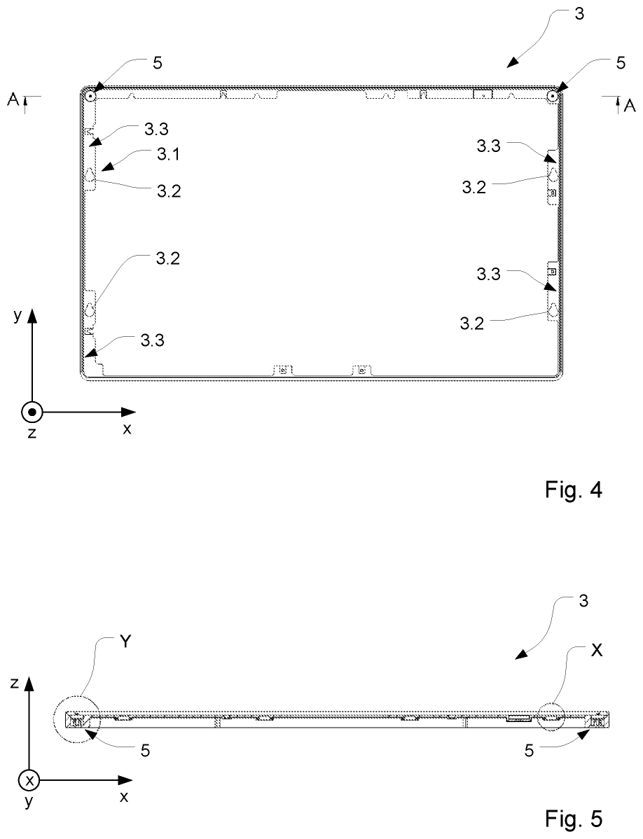

FIG. 4 shows by way of example a view of the rear side of a first housing part, to which the second housing part can be fastened;

FIG. 5 shows by way of example a sectional view through the first housing part along the intersection line A-A according to FIG. 4;

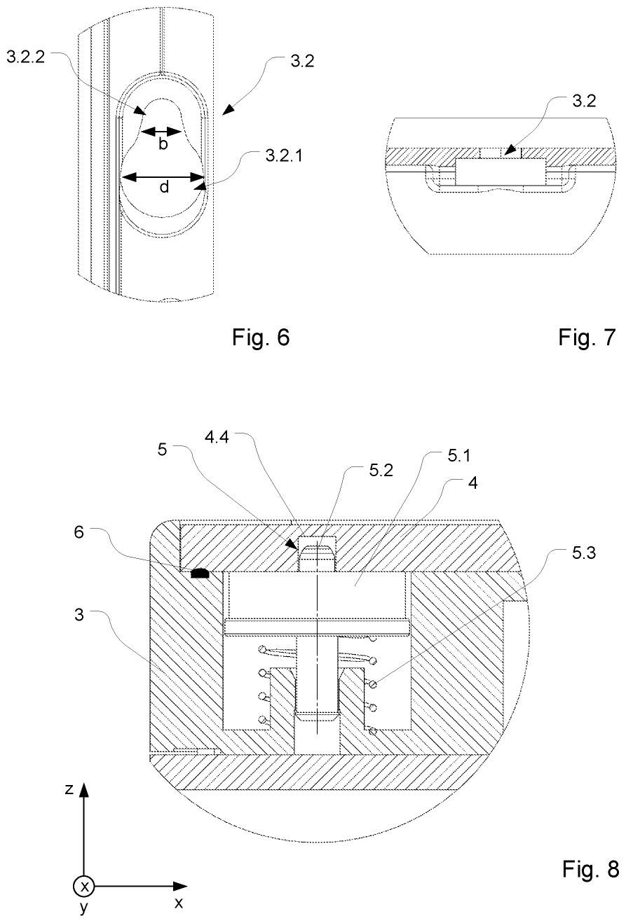

FIG. 6 shows by way of example a detailed view of the keyhole-like opening of the first housing part;

FIG. 7 shows by way of example a detail marked with X according to FIG. 5 in an enlarged view;

FIG. 8 shows by way of example an enlarged view of the detail marked with Y according to FIG. 5;

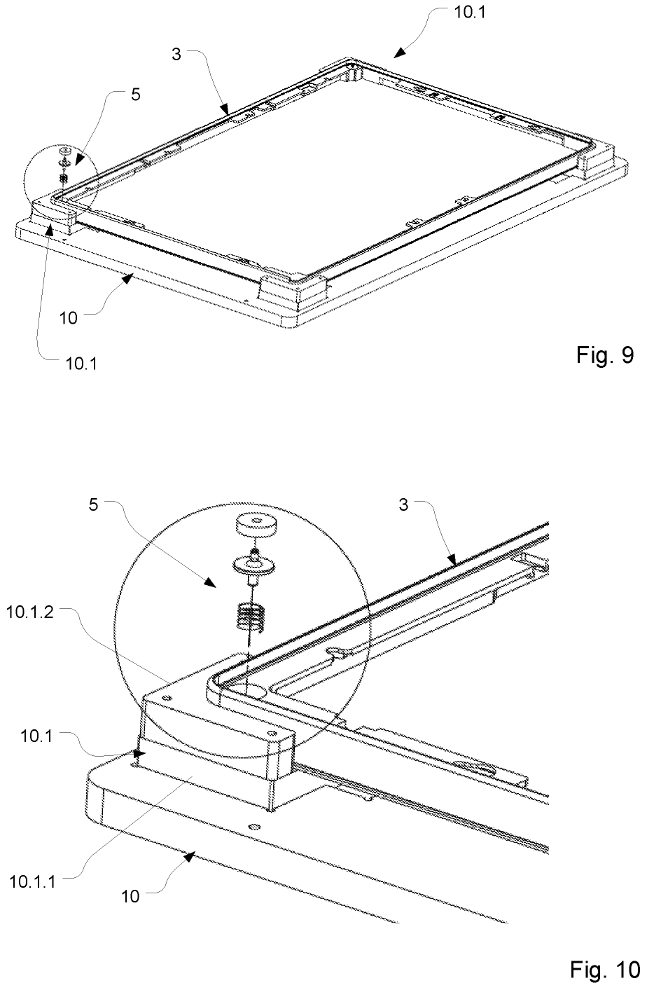

FIG. 9 shows by way of example a perspective view of a first housing part inserted into the detaching device with a securing member illustrated in an exploded view;

FIG. 10 shows a detailed view of a corner area of the first housing part inserted into the detaching device according to FIG. 9;

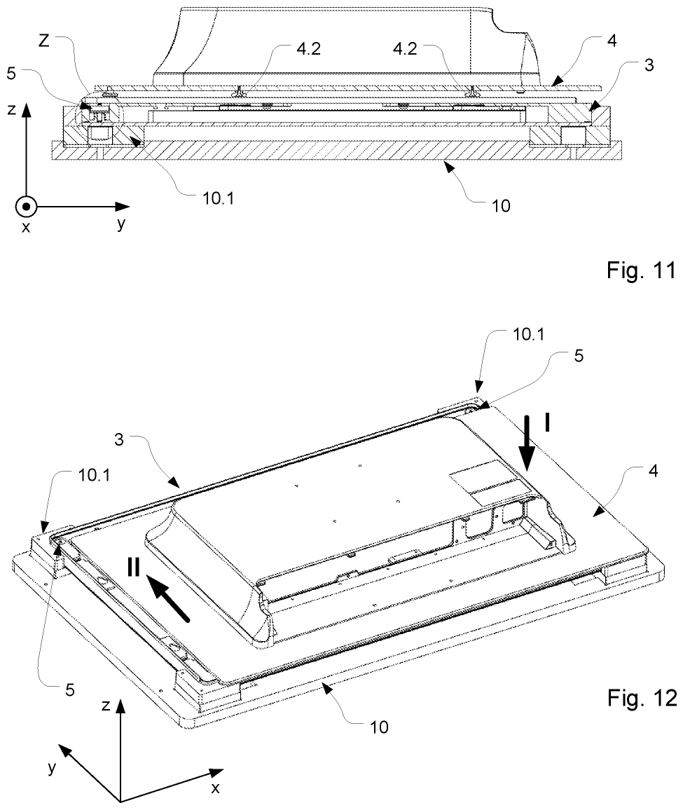

FIG. 11 shows a lateral sectional view of a first housing part inserted into the detaching device with a second housing part arranged thereabove;

FIG. 12 shows a view comparable to that of FIG. 11 in a perspective view;

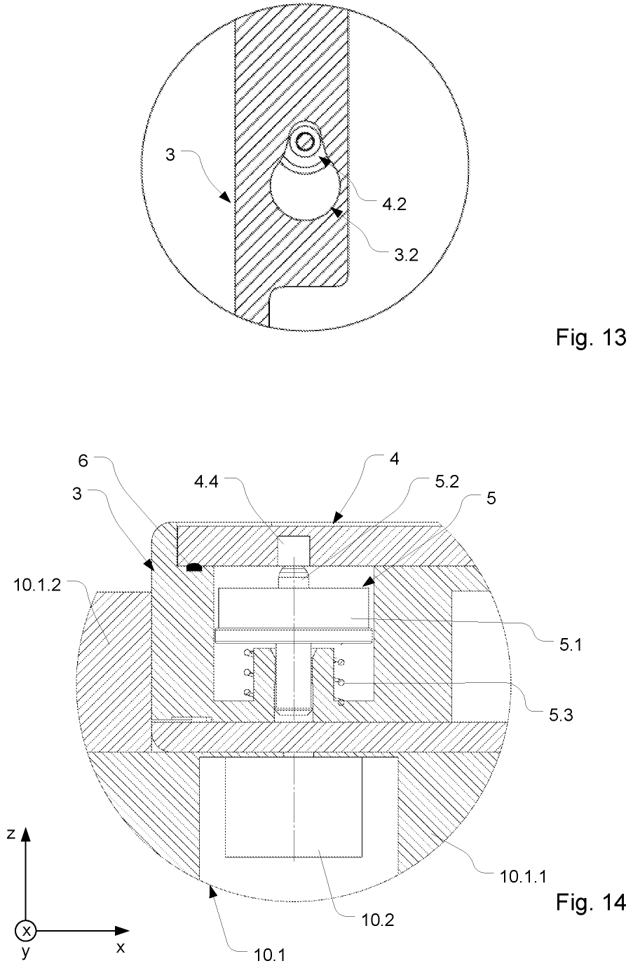

FIG. 13 shows a detailed view of the interlocking connection between the first and second housing parts, wherein a pin having the shape of a mushroom meshes with a keyhole-like opening;

FIG. 14 shows by way of example an enlarged view of the detail marked with Z according to FIG. 11;

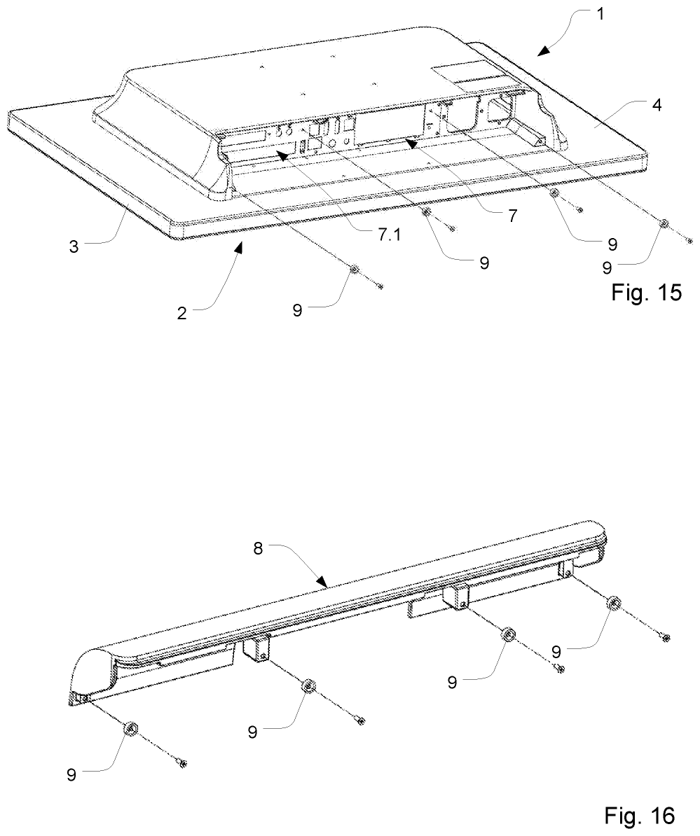

FIG. 15 shows by way of example a housing with a connection area, in which the magnetic elements are shown in an exploded view in a detached manner;

FIG. 16 shows by way of example a housing cover provided for closing a connection area, in which the magnetic elements are shown in an exploded view in a detached manner;

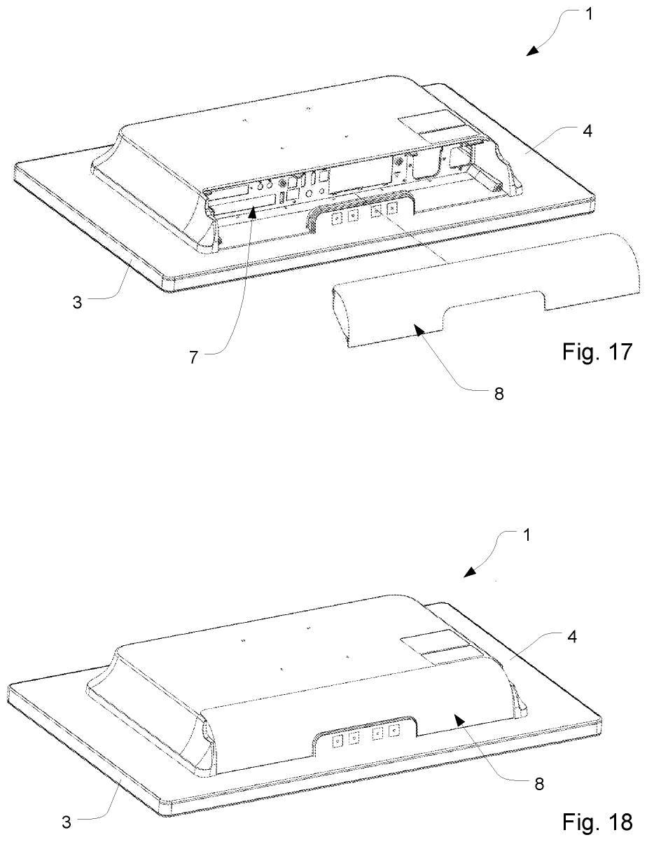

FIG. 17 shows by way of example the housing according to FIG. 15 with a removed housing cover in an exploded view; and

FIG. 18 shows by way of example the housing according to FIG. 17 with the housing cover in place.

FIG. 1 shows a perspective view of a housing 1. The housing 1 is the housing of a medical device, in particular of a touch-sensitive display unit or a screen or a computer unit which includes such a display unit or such a screen. Therefore, at least one display unit 2 is accommodated in the housing 1 or the housing 1 has a mechanical support for a housing of this type.

The housing 1 is composed of several parts. It comprises a first housing part 3 and a second housing part 4. The first housing part 3 forms, for example, a frame-like housing part which accommodates the display unit 2. The second housing part 4 is a housing part to be arranged on the rear side of housing 1, i.e. the second housing part 4 is arranged on the rear side behind the display unit 2.

When the housing 1 is closed, the first and second housing parts 3, 4 are firmly but detachably connected to each other. The mechanical connection of the housing parts 3, 4 and the securing members for securing the closed state of housing 1 are described in more detail below.

FIGS. 2 and 3 show the second housing part 4 and FIGS. 4 and 5 show the first housing part 3, in each case in different views.

For the detachable connection of the first and second housing parts 3, 4, the first housing part 3 has first connecting members 3.1 and the second housing part 4 has second connecting members 4.1. These connecting members 3.1, 4.1 are shaped in such a way that they allow an interlocking connection between the first and second housing parts 3, 4. The interlocking connection can be made possible in particular by hooking or intermeshing the housing parts 3, 4 into each other.

In the embodiment shown according to FIGS. 2 to 5, the second housing part 4 has projections 4.2 as second connecting members 4.1. In an embodiment, as the first connecting members 3.1, the first housing part 3 has openings 3.2 which cooperate with these projections 4.2 when the housing 1 is closed, in such a way that an interlocking connection is established between the projections 4.2 and the openings 3.2.

As shown in FIGS. 2 and 3, the projections 4.2 of the second housing part 4 are pins which are shaped like a mushroom head, for example. These pins have e.g. a first pin part 4.2.1 and a second pin part 4.2.2. The diameter of the first pin part 4.2.1 is here smaller than the diameter of the second pin part 4.2.2. These pins or projections 4.2 protrude from a contact surface 4.3, in particular at right angles, as shown in FIG. 3. As a result, when the contact surface 3 is in contact with a corresponding contact surface of the first housing part 3, the pins or projections 4.2 can engage in openings 3.2 provided on the first housing part 3.

It goes without saying that the mushroom-headed design of the projections 4.2 is only an embodiment and that there are other interlocking connection possibilities, e.g. dovetail-like connections or the like.

FIGS. 4 and 5 show the design of the first housing part 3 with its first connecting members 3.1. The first housing part 3 has, for example, a contact area 3.3, with which the second housing part 4 comes into contact. This also includes the fact that the second housing part 4 does not contact the contact area 3.3 directly but indirectly via a seal 6.

In the first housing part 3, openings 3.2 corresponding to the projections 4.2 of the second body section 4 are provided. “Corresponding” in this context means that the openings 3.2 are arranged on the first housing part 3 in such a way that when the second housing part 4 is placed on the first housing part 3 (according to the applicable coordinate system by a placement movement in the negative z direction) the projections 4.2 can be inserted into the openings 3.2. The openings 3.2 are here provided, for example, at two opposite edge areas of the first housing part 3, in particular the narrow sides thereof.

The openings 3.2 are adapted, with regard to shape, to the projections 4.2 of the second housing part 4. In the illustrated embodiment, the openings 3.2 are designed in a drop-like or keyhole-like shape in order to be able to establish an interlocking connection with the pins of the second housing part 4 that are shaped like a mushroom head.

More in detail, as can be seen in particular in FIGS. 6 and 7, the openings 3.2 have a first opening section 3.2.1 and a second opening section 3.2.2 which extends in a radial direction away from the first opening section 3.2.1. In this case, the first opening section 3.2.1 has a diameter d which is larger than the width b of the second opening section 3.2.2. The diameter d and the width b are here selected in such a way that the second pin part 4.2.2 can be passed through the first opening section 3.2.1 (according to the current coordinate system by a placement movement in the negative z-direction) and, after a shifting movement of the second housing part 4 in the direction in which the second opening section 3.2.2 extends (according to the current coordinate system by a shifting movement in the positive y-direction), the second pin part 4.2.2 engages behind the second opening section 3.2.2, so that an interlocking connection is established between the housing parts 3, 4.

It is understood that the shape of the openings 3.2 must be adapted to the shape of the projections 4.2. For example, if the projections 4.2 have the shape of a dovetail, the openings 3.2 must have an opening shape that corresponds to this dovetail shape.

In order to avoid screw connections between the first and second housing parts 3, 4, the housing 1 has securing members 5. These securing members are made e.g. in such a way that they are concealed, i.e. they are not visible from the outside when the housing is closed.

In an embodiment, the securing members 5 are configured to prevent a relative movement of the housing parts 3, 4 in order to secure the interlocking connection between the first and second housing parts 3, 4 because this relative movement would lead to a detachment of this interlocking connection. The securing members are movably held in the housing 1, in particular in the first housing part 3, and can be moved by a detaching device 10 from a securing position (shown in FIG. 8) to a detaching position (shown in FIG. 14).

In the illustrated embodiment, the securing members 5 have a latch 5.2 which is movably held in the first housing part 3. Alternatively, an inverse configuration would also be conceivable in principle, namely that the securing members 5 are provided in the second housing part 4. In particular, the latch 5.2 can be moved from a securing position shown in FIG. 8 to a detaching position shown in FIG. 14.

In the illustrated embodiment, the latch 5.2 is configured in such a way that it can be linearly shifted. Alternatively, the latch 5.2 can also be movable in other ways, e.g. pivotable or in a combined linear/swivel movement. In the illustrated embodiment, the latch 5.2 is a locking bolt.

The latch 5.2 is pretensioned into a securing position in a spring-loaded fashion as shown in FIG. 8. A spiral spring 5.3 surrounding the latch 5.2 is provided for this purpose, for example, and presses the latch 5.2 into an advanced position (securing position) by means of its spring force. In this securing position, the latch 5.2 is inserted at least in sections into a recess 4.4 of the second housing part 4 when the second housing part 4 is placed on. This engagement of the latch 5.2 in the recess 4.4 prevents a shifting of the second housing part 4 relative to the first housing part 3. This is achieved in particular by the fact that the latch 5.2 can be moved in a direction (z-direction) transversely, in particular perpendicularly, to the shifting direction (y-direction), by means of which the interlocking connection between the first and second housing parts 3, 4 is released.

The securing members 5 have an element 5.1 which is either magnetic itself, i.e. comprises e.g. a permanent magnet, or at least consists of a ferromagnetic material, for example iron, cobalt or nickel, in order to be able to cooperate with a magnetic element 10.2 of the magnetic detaching device 10.

In the illustrated embodiment, the magnetic or magnetizable element 5.1 is, for example, concentrically applied to the latch 5.2 and connected thereto. As described in more detail below, the magnetic or magnetizable element 5.1 is configured to move or pull the latch 5.2 from the securing position shown in FIG. 8 against the spring force into the detaching position, when a magnetic element 10.2 of the magnetic detaching device 10 is arranged below the securing member 5 (FIG. 14). As a result, the latch 5.2 is pulled back from the recess 4.2 and the interlocking connection between the first and second housing parts 3, 4 can be released.

FIG. 10 shows the securing members 5 in an exploded view. The securing members comprising the latch 5.2 and the spiral spring 5.3 are inserted into a recess in the corner area of the first housing part 3, as can be seen by a person skilled in the art in conjunction with FIG. 8.

In an embodiment, a plurality of securing members 5 are distributed at different positions on the housing 1. In an embodiment, as shown in FIG. 4, at least two securing members 5 are provided on the two opposite sides or corner areas of the first housing part 3 in order to be able to block the relative movement of the housing parts 3, 4 on both sides by shifting them in the y-direction.

In the following, the process of closing the housing 1 by fastening the second housing part 4 to the first housing part 3 is described on the basis of FIGS. 9 and FIGS. 11 to 14.

First, the first housing part 3 is inserted or placed in the magnetic detaching device 10. The insertion is done, for example, in such a way that the display unit 2 provided in the first housing part 3 faces the magnetic detaching device 10. The detaching device 10 has a contact section 10.1 with which the first housing part 3 comes into contact when it is inserted. In particular, the contact section 10.1 comprises a bottom-side contact section area 10.1.1 and a lateral contact section area 10.1.2. The bottom-side contact section area forms a contact surface with regard to a front side of the first housing part 3, into which the display unit is integrated. The lateral contact section area 10.1.2, on the other hand, forms a kind of lateral stop, with regard to which a lateral surface or a corner region of the first housing part 3 comes into contact. As a result, the first housing part 3 can be positioned precisely with respect to the magnetic detaching device 10.

It should be noted that the detaching device 10 can be made of one part as shown in FIG. 9. Alternatively, it can consist of a plurality of parts, each of which must be positioned individually relative to the first housing part 3.

In the detaching device 10, magnetic elements 10.2 are provided which are assigned to the respective securing members 5 or latches 5.2. After the insertion into the detaching device 10, the respective securing members 5 with their magnetic or magnetizable elements 5.1 are arranged relative to the magnetic elements 10.2 in such a way that the respective magnetic elements 10.2 exert a force on the elements 5.1 due to the magnetic field so that the latches 5.2 are moved or pulled back into the detaching position as shown in FIG. 14.

Then, the second housing part 4 can be placed on the first housing part and fastened. For this purpose, the second housing part 4 is placed on the first housing part 3 in a first spatial direction, in the illustrated embodiment in negative z-direction, as indicated by the arrow I. As a result of this placement movement, the second housing part 4 with its contact surface 4.3 comes into contact with the seal 6. The projections 4.2 are inserted through the opening 3.2, in particular the first opening section 3.2.1.

The second housing part 4 is then shifted relative to the first housing part 3 in a second spatial direction which is transverse to the first spatial direction. In the embodiment, this second spatial direction corresponds to the positive y-direction. As a result, a positive engagement is achieved between the projections 4.2 and the openings 3.2, i.e. the projections engage behind sections of the openings. This can be seen by way of example in FIG. 13.

In order to prevent an unwanted release of the interlocking connection between the first and second housing parts 3, 4, in particular to prevent shifting of the second housing part 4 relative to the first housing part 3, the securing members 5 are activated after establishing the interlocking connection, i.e. positioned in the securing position.

The securing members 5 are activated by removing the housing 1, i.e. the first housing part 3 with the second housing part 4 fastened thereto, from the detaching device 10. By moving the housing 1 away from the detaching device 10, the magnetic field acting on the securing members 5 weakens and the securing members move into the securing position or locking position due to the spring load. Therefore, after the removal of housing 1 from the detaching device 10, the second housing part 4 can no longer be moved, in particular shifted, relative to the first housing part 3.

The opening of the housing 1, i.e. the removal of the second housing part 4 from the first housing part 3, is done in a similar way, namely by arranging the housing 1 on the magnetic detaching device 10 to move the securing members 5 into the detaching position, shifting the second housing part 4 relative to the first housing part 3 and removing the second housing part 4 after this shifting movement.

As shown in particular in FIGS. 8, 10 and 15, a seal 6 is provided circumferentially at the interface between the first and second housing parts 3, 4. The seal 6 ensures that the housing 1 is fluid-tight. Here, “fluid-tight” means in particular that the interface between the first and second housing parts 3, 4 is dust-tight and protected against water jets from any angle (IP65 protection class).

In order to achieve a secure sealing of the interface but still be able to shift the second housing part 4 relative to the first housing part without shifting the seal, the following designs are advantageous. In an embodiment, the seal 6 is formed in one piece circumferentially and is partially inserted into a bead of the first housing part 3 or second housing part 4. In an embodiment, more than 50% of the height of the seal is inserted into the bead, so that the seal 6 with its smaller part of the height protrudes beyond the bead. In addition, the seal 6 is advantageously fastened in the bead in a clamping or and/or integral-bonding manner, so that the seal 6 cannot detach from the bead when the housing parts 3, 4 are shifted relative to each other.

The seal advantageously has a half-round or semicircular cross-section, wherein a flat side of the seal 6 is accommodated in the bead and the rounding of the seal 6 protrudes beyond the top side of the bead. This results in a better shiftability of the housing parts 3, 4 relative to each other. In addition, the seal can have a sliding layer, e.g. applied by a sliding spray or the like, to improve the sliding ability.

In an embodiment, by establishing the interlocking connection between the first and second housing parts 3, 4, one of the housing parts 3, 4, in particular the second housing part 4, is pressed against the seal 6 in order to achieve the tightness of the housing 1.

FIGS. 15 to 18 show an embodiment of the housing 1, in which the second housing part 4 has a housing cover 8 which can be fastened in a detachable manner. The housing cover 8 is in particular intended to cover or close a connection area 7, on which, for example, a plurality of plug connection points 7.1 is provided. For this purpose, the second housing part 4 has a recess or opening into which the housing cover 8 can be inserted.

In order to fasten the housing cover 8 to the second housing part 4, the housing cover 8 and/or the second housing part 4 has a plurality of magnet elements 9. In an embodiment, magnet elements 9 are provided on both the housing cover 8 and the second housing part 4, which interact with each one another and are arranged in a locally corresponding way. As a result, after placing the housing cover 8 on the second housing part 4 (FIG. 17), the housing cover 8 is magnetically held on the second housing part 4 as shown in FIG. 18.

The housing 1 can be at least partially made of aluminum die-cast. In particular, the first and/or second housing part 3, 4 and/or the housing cover 8 can be manufactured using an aluminum die-casting method.

The present disclosure was described above by means of embodiments. It goes without saying that numerous modifications and alterations are possible without leaving the inventive concept underlying the invention defined by the claims.

### List of Reference Signs

1 housing

2 display unit

3 first housing part

3.1 first connecting members

3.2 opening

3.2.1 first opening section

3.2.2 second opening section

3.3 contact area

4 second housing part

4.1 second connecting members

4.2 projection

4.2.1 first pin part

4.2.2 second pin part

4.3 contact surface

4.4 recess

5 securing members

5.1 magnetic or magnetizable element

5.2 latch

5.3 spiral spring

6 seal

7 connection area

7.1 plug connection point

8 housing cover

9 magnet element

10 magnetic detaching device

10.1 contact section

10.1.1 bottom-side contact section area

10.1.2 lateral contact section area

10.2 magnet element

d diameter

b width

1. A housing for a medical device comprising at least one touch-sensitive display unit or a support for a touch-sensitive display unit, wherein the housing comprises at least a first housing part and a second housing part, which can be detachably connected to the first housing part, wherein the first housing part has first connecting members and the second housing part has second connecting members cooperating with these first connecting members, wherein the first and second connecting members are configured to fasten the second housing part to the first housing part by means of an interlocking connection, wherein the interlocking connection is obtained by a hooking or meshing connection of the housing parts, wherein the second housing part is configured to be fastened to the first housing part by putting it on in a first spatial direction and by shifting it in a second spatial direction extending transversely to the first spatial direction, wherein securing members are provided which are configured to secure the fastening of the second housing part to the first housing part, wherein the securing members include a magnetic or magnetizable element which is configured to cooperate with a magnetic detaching device in such a way that the securing members can be moved from a securing position to a detaching position by the magnetic field of the magnetic detaching device.

2. The housing according to claim 1, wherein the securing members comprise a latch which is positioned in a spring-loaded manner in a securing position without the influence of external forces.

3. The housing according to claim 2, wherein the latch can be shifted, pivoted or moved in a combined shifting and pivoting movement.

4. The housing according to claim 2, wherein the latch is mechanically coupled to the magnetic or magnetizable element, the magnetic or magnetizable element being configured to cooperate with the magnetic detaching device in such a way that due to the forces exerted by the magnetic detaching device on the magnetic or magnetizable element the latch can be moved from the securing position to the detaching position.

5. The housing according to claim 2, wherein the latch is provided in the securing position for engaging in a recess formed on the second housing part or engages behind a projection or an undercut provided on the second housing part in the securing position.

6. The housing according to claim 1, wherein the first housing part has openings as first connecting members, in which projections provided on the second housing part as second connecting members engage in an interlocking manner or
the second housing part has openings as second connecting members, in which projections provided on the first housing part as first connecting members engage in an interlocking manner.

7. The housing according to claim 1, wherein the interlocking connection of the second housing part to the first housing part is effected by a projection which engages behind an undercut in sections.

8. The housing according to claim 1, wherein the interlocking connection of the second housing part to the first housing part is effected by a plurality of projections, which are shaped like mushroom heads or dovetails and engage in recesses or openings cooperating with these projections.

9. (canceled)

10. The housing according to claim 1, wherein the first and second spatial directions are perpendicular to each other.

11. The housing according to claim 1, wherein a seal is provided at the interface between the first and second housing parts (3, 4) and seals the interface in a liquid-tight manner when the second housing part is fastened to the first housing part.

12. The housing according to claim 1, wherein when the second housing part is fastened to the first housing part, the transition between the first and second housing parts is flush-mounted.

13. The housing according to claim 1, wherein at least one connection area with at least one plug-in connection interface is provided on the second housing part, and wherein a housing cover is provided for closing the connection area, which cover can be magnetically fixed to the second housing part.

14. (canceled)

15. A method for opening a housing of a medical device comprising at least one touch-sensitive display unit or a support for a touch-sensitive display unit, the housing comprising at least a first housing part and a second housing part, which can be detachably connected to the first housing part, wherein the first housing part has first connecting members and the second housing part has second connecting members cooperating with these first connecting members, wherein the first and second connecting members are configured to fasten the second housing part to the first housing part by means of an interlocking connection, wherein the interlocking connection is obtained by a hooking or meshing connection of the housing parts, wherein the second housing part is configured to be fastened to the first housing part by putting it on in a first spatial direction and by shifting it in a second spatial direction extending transversely to the first spatial direction, wherein securing members are provided, which are configured to secure the fastening of the second housing part to the first housing part, the method comprising the following steps:
arranging the housing, in which an opening of the first housing part is closed by the second housing part, on a magnetic detaching device;
moving the securing members from a securing position to a detaching position by applying a magnetic field of the magnetic detaching device to the securing members;
opening the housing by removing the second housing part from the first housing part.
